(19) United States
(12) Patent Application Publication
(10) Pub. No.: US 2025/0239386 A1
(43) Pub. Date: Jul. 24, 2025

(54) System and Method To Handle Lax Objects

(71) Applicant: TE Connectivity Solutions GmbH, Schaffhausen (CH)

(72) Inventors: Swapnilsinh Solanki, Middletown, PA (US); Edward T. Price, III, Middletown, PA (US)

(73) Assignee: TE Connectivity Solutions GmbH, Schaffhausen (CH)

(21) Appl. No.: 19/026,912

(22) Filed: Jan. 17, 2025

Related U.S. Application Data
(60) Provisional application No. 63/623,991, filed on Jan. 23, 2024.

(51) Int. Cl. H01B 13/00; G01N 21/88; G01N 21/89; G01N 21/952

(52) U.S. Cl. CPC H01B 13/0003; G01N 21/8851; G01N 21/8914; G01N 21/952

(57) ABSTRACT

A system adapted to inspect an object including a flexible wire includes a feed device feeding the object toward an inspection device, a magnet and a wire holding fixture. The magnet is adapted to secure to the flexible wire of the object as it approaches the inspection device. The wire holding fixture engages with the wire secured by the magnet and maintains the wire in a predetermined position relative to the object being inspected, and outside of a field of detection of the inspection device.

### CROSS-REFERENCE TO RELATED APPLICATION(S)

This application claims the benefit of U.S. Provisional Patent Application No. 63/623,991, filed Jan. 23, 2024, the entire disclosure of which is incorporated by reference herein.

### FIELD OF THE INVENTION

The present disclosure relates to object inspection systems, and more particularly, to a visual inspection system for inspecting articles which include lax or flexible components, such as polymer products which include exposed flexible wires.

### BACKGROUND

During manufacturing it is often desired to inspection a product to ensure required accuracy and/or detect defects, by way of example only. Some inspection systems rely on the use of cameras for imaging a product, and subjecting those images to analysis to detect defects. Thus, accurate inspection and/or product imaging requires the precise handling of the product during inspection. This is particularly problematic when some or all of the product is flexible or lax in nature. For example, some mandrel formed polymer products utilize flexible metal wires bonded therewith in order to affect its desired functionality. The presence of these wires, and in particular at locations where they may exit the underlying product and thus are not under control, can interfere with the inspection process. Improved systems and methods for accurately inspecting these and other types of products are desired.

### SUMMARY

According to an embodiment of the present disclosure, a system adapted to inspect an object including a flexible wire includes a feed device feeding the object toward an inspection device, a selectively movable magnet and a selectively movable wire holding fixture. The magnet is adapted to secure to the flexible wire of the object as it approaches the inspection device. The wire holding fixture engages with the wire secured by the magnet and maintains the wire in a predetermined position relative to the object being inspected, and outside of a field of detection of the inspection device.

### BRIEF DESCRIPTION OF THE DRAWINGS

The invention will now be described by way of example with reference to the accompanying Figures, of which:

FIG. 1 is an orthogonal view of an exemplary product to be inspected useful for describing embodiments of the present disclosure;

FIG. 2 is a partial orthogonal view of an inspection system according to an embodiment of the present disclosure;

FIG. 3 is another partial orthogonal view of the inspection system of FIG. 2;

FIG. 4 is a simplified front view of a produce under inspection by the inspection system of the present disclosure; and

FIG. 5 is a simplified process diagram illustrating a flexible object handling process utilized by the inspection system of the present disclosure.

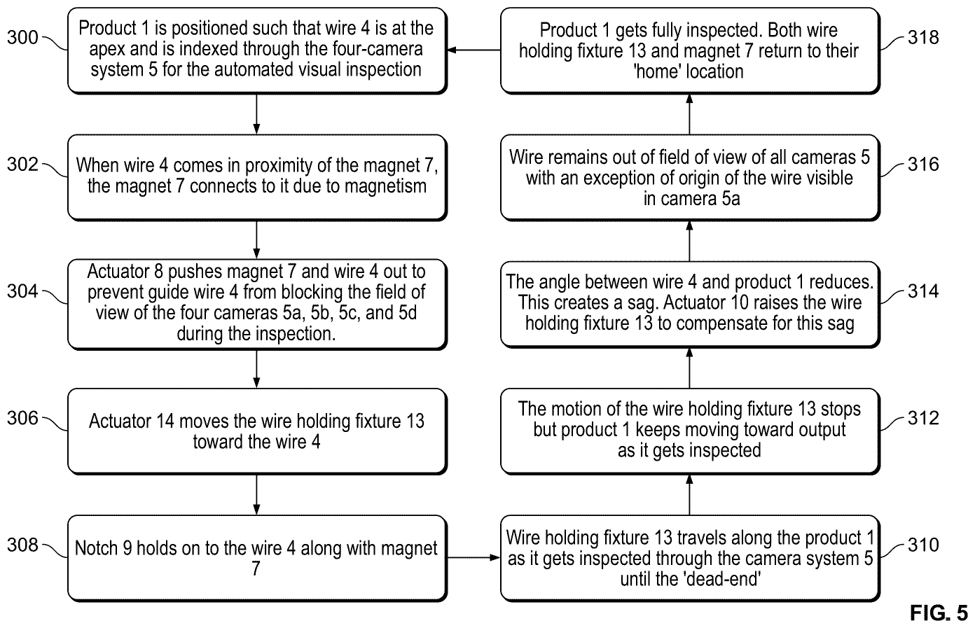

### DETAILED DESCRIPTION OF THE EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

According to an embodiment of the present disclosure, a system for visually inspecting an object including a flexible wire is provided. The system generally includes an inspection device (e.g., a plurality of cameras), and is adapted to receive the object to be inspected in a feed direction (e.g., alone an elongated longitudinal axis of the object). The system further includes a magnet configured to secure the flexible wire of the object as it approaches the inspection device, and before it enters a field of view of the inspection device. A first actuator is provided for biasing the magnet and the wire captured thereby from a first position proximal to the object to be inspected to a second position distal to the object to be inspected. Once moved away from the object, a wire holding fixture of the system captures the wire from the second position. A second actuator then translates the wire holding fixture and the wire toward the visual inspection device in the feed direction, as the object to be inspected also approaches the visual inspection device. During translation, the wire holding fixture maintains the wire in a position outside of one or more fields of view of the inspection device. As the wire holding fixture is unable to translate further due to mechanical blockage (e.g., resulting from space limitations of the inspection device and/or inspection system), a third actuator raises or further biases the wire holding fixture, and thus the wire, away from the object, preventing it from sagging or arcing, and ensuring it remains outside of the viewing field(s) of the inspection device as the object inspection is completed.

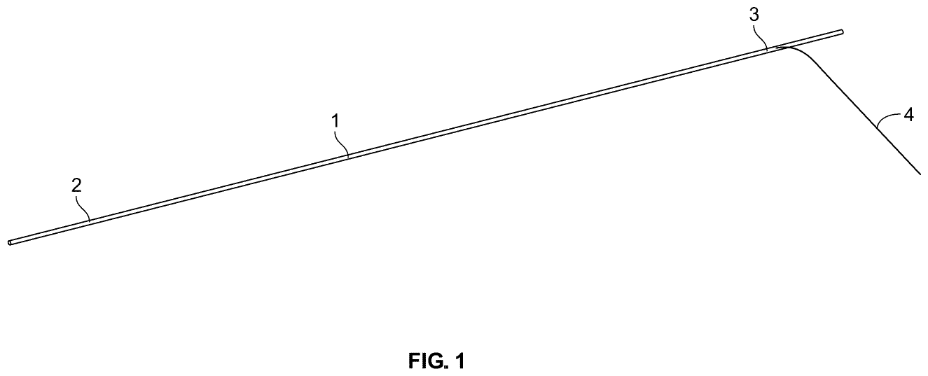

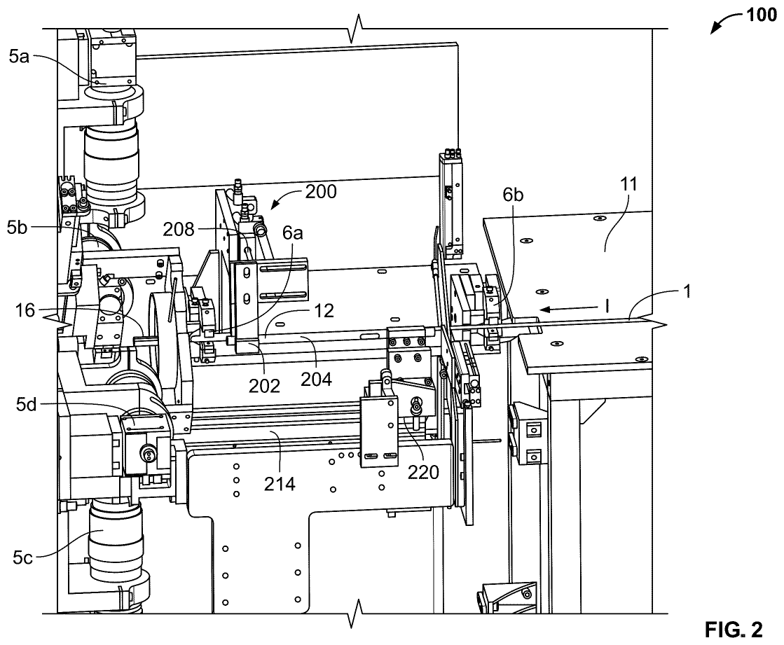

Referring generally to FIG. 1, an exemplary product 1 useful for describing the system of the present disclosure may include, for example, a mandrel formed polymer body (e.g., an elongated cylindrical body) onto or into which one or more wires 4 is bonded along its axial direction. The product 1 includes a first end 2 to be fed into an inspection device first, and a second end 3. In order to ensure product quality, the product 1 must be inspected along its length via a product inspection system 100, as shown in FIG. 2.

The presence of the wire 4 creates difficulties during an inspection process of the product 1. Specifically, if the exposed wire 4 is captured by imaging devices of the inspection system 100, the image analyzing algorithms adapted to detect defects in the product 1 utilized by the system will often mistake the wire for a defect in the product (e.g., a crack or rupture). Accordingly, as the wire 4 at the end 3 of the product 1 nears the inspection system 100, and specifically the imaging device(s) thereof, the position of the wire 4 must be accurately controlled. For example, the wire 4 must be biased out of a field of view of the system's imaging devices during the inspection process, positioned to limit its visibility, and/or maintained in a consistent, predictable position relative to the product 1 so it can be identified and masked or discarded during image processing.

Referring to FIG. 2, the exemplary inspection system 100 includes a plurality of inspection devices, such as imaging devices or cameras. More specifically, the exemplary inspection system 100 includes four cameras 5a, 5b, 5c and 5d arranged radially about a central axis of the product 1, or the axis of elongation of the product. In the exemplary embodiment, the cameras 5a, 5b, 5c, 5d are arranged at 90 degree increments about the product 1, such that images of a top, bottom, left and right side of the product 1 are captured. As shown, the cameras 5a, 5b, 5c, 5d are adapted to image segments of the product 1 as it passes through a funnel 16.

The product 1 is fed, for example, from a table 11 in an inspection or feed direction I, parallel (or coaxial) to the axis of the product. The product 1 may be automatically fed via pairs of grippers 6a, 6b arranged along the product 1 in the feed direction I. The grippers 6a, 6b are adapted to grasp the product 1, and incrementally move or index it in the feed direction I. Of course, other types of feed elements may be used, such as rollers or the like.

As the camera 5a, 5b, 5c, 5d image the product 1, associated image processing software analyzes images of the product in order to detect defects in the product. This may include, for example, taking measurements of the product to detect dimensions for determining if the product 1 falls outside predetermined acceptable ranges or tolerances, inspecting the surface of the product for structural defects, such as cracks, linearity, and the like. If the inspection system 100 detects a defect, the product 1 can be flagged as rejected, and pulled from further manufacturing, processing, or packaging.

As can be visualized from FIGS. 1 and 2, at the start of an inspection cycle, the wire 4 is exposed only on the end 3 of the product 1. However, when the product 1 has indexed sufficiently such that the wire 4 reaches a location 12 proximate the visual inspection devices (e.g., the cameras), the position of the exposed wire 4 must come under control of the system. This is achieved by a wire handling mechanism 200 according to an embodiment of the present disclosure.

The wire handling mechanism 200 ensures that the wire 4 remains out of a field of view of at least a portion of the cameras 5a, 5b, 5c, 5d. In one embodiment, the mechanism 200 is operative to move the wire 4 such that is not visible to any of the cameras 5a, 5b, 5c, 5d, or to be visible only to, for example, camera 5a for a limited time. During this time, the wire 4 can be masked during image processing as it is held in a consistent position by the handling mechanism 200.

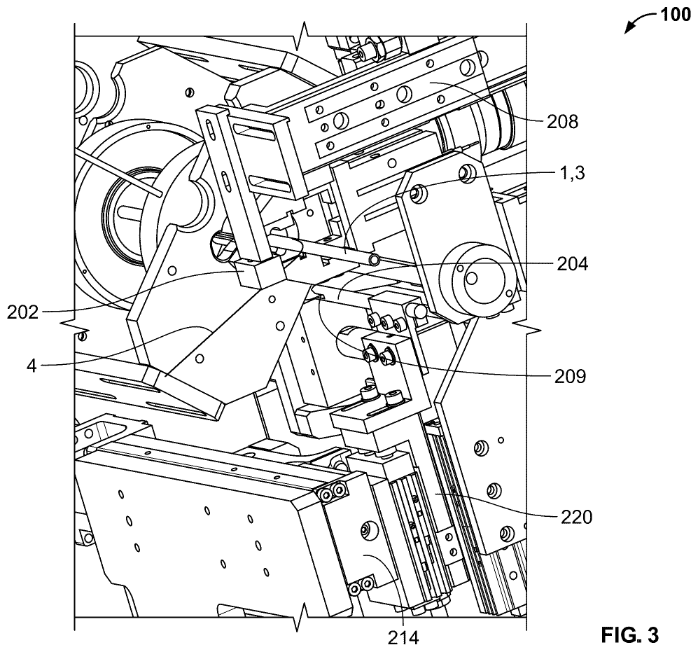

Referring generally now to FIGS. 2 and 3, the function of the wire handling mechanism 200 will now be described. In one embodiment, the wire handling mechanism 200 includes a movable magnet 202 and a movable wire holding fixture 204. Due to the magnetic properties of the wire 4, as it approaches the magnet 202 proximate the location 12, it attaches thereto. With particular reference to FIG. 3, a detailed view of the magnet 202 contacting and holding the wire 4 is shown.

Once the wire 4 is attached to the magnet 202, an actuator 208 extends the magnet outwardly (i.e., horizontally) and away from the product 1. The resulting extended position of the wire 4 permits engagement of the wire by the wire holding fixture 204. Of note, the wire holding fixture 204 operates on a 2-axis system. In particular, an actuator 214 operates to allow the wire holding fixture 204 to travel along the major axis of the product 1 (i.e., in the feed direction), and an actuator 220 enables the wire holding fixture 204 to travel in a vertical direction. As the actuator 208 extends the magnet 202 outwardly along with the wire 4, the actuator 214 moves the wire holding fixture 204 toward the wire 4, such that a notch 209 defined on an end thereof captures the wire.

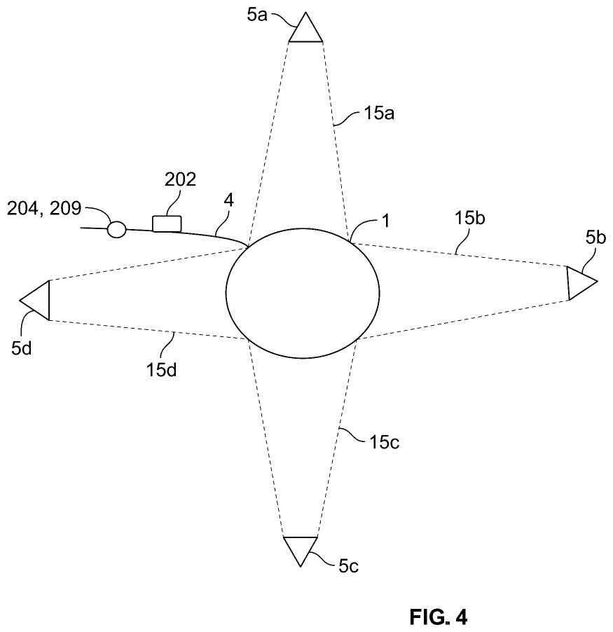

With the wire 4 captured by the wire holding fixture 204, further indexing of the product 1 is matched by like indexing of the wire holding fixture 204 (and thus the wire 4 held in the notch 209) via the actuator 214. This matching indexing maintains a consistent orientation of the wire 4 relative to the cameras 5a, 5b, 5c, 5d. More specifically, FIG. 4 shows a cross-sectional representation of the wire 4 attached to the magnet 202, and arranged within the notch 209 of the wire holding fixture 204. As shown, the wire 4 is held outside of the field of views 15a, 15b, 15c, and 15d of the respective cameras 5a, 5b, 5c, 5d. In this way, the mechanism 200 is operative to maintain the wire 4 in an ideal position as the product 1 is inspected.

It should be understood from FIGS. 2 and 3 that as the wire holding fixture 204 approaches the area of the funnel 16, it is physically prevented from indexing any further in the feed direction. At this point, motion of the wire holding fixture 204 is stopped but product 1 is required to continue moving in the feed direction. As a result, an angle between wire 4 and the major axis of product 1 slowly decreases. This creates a bend, arc or sag in the wire 4 toward an end of the inspection process. In order to remedy this, the actuator 220 is adapted to raise the wire holding fixture 204 vertically to compensate for the bend so that the wire 4 does not fall within the field of view of each of at least cameras 5a, 5b, 5c, 5d, although the wire 4 may be initially visible in the field of view 15a of the camera 5a at the start of the wire handling process. However, this segment of the wire can be accounted for during inspection process. In this way, the mechanism 200 ensures that the wire 4 doesn't hinder the inspection of the product throughout the majority of the cycle.

FIG. 4 provides a simplified flow chart illustrating the above described function of a system according to an embodiment of the present disclosure.

In a first step 300, a linear product including a wire extending from an end thereof is indexed through a four camera inspection system.

In a step 302, the wire comes into contact with and connects to a magnet.

In a step 304, an actuator biases the magnet and attached wire away from the product to prevent the wire from entering or blocking the field of view of the cameras during inspection.

In a step 306, once the wire is biased by the magnet, another actuator moves a wire holding fixture toward the wire.

In a step 308, a notch defined in the wire holding fixture captures the wire.

In a step 310, the wire holding fixture travels in the feed direction along with the product during its inspection until it is unable to travel further due to physical blockage of the system.

In a step 312, motion of the wire holding fixture is halted, with the product continuing to move through inspection.

In a step 314, as an angle of the wire relative to the product decreases (e.g., from sagging or bending resulting from the stationary holding fixture), another actuator raises the wire holding fixture to mitigate this reduction in relative angle or bend in the wire.

In a step 316, the wire remains outside of a view of each of the cameras during further inspection.

In a step 318, the product inspection is completed and the wire holding fixture and magnet return to respective initial or home positions.

It should be understood that the systems and methods described herein may be performed automatically, and more specifically, all or portions of the described operations may be accomplished under computer control (i.e., control by one or more processors or digital control devices, such as application specific circuits and the like) executing a set of program instructions stored in one or more memory devices. These automated control systems, including associated sensors, are outside of the focus of this description, and have been omitted only for the purpose of brevity.

In addition, those areas in which it is believed that those of ordinary skill in the art are familiar, have not been described herein in order not to unnecessarily obscure the invention described. Accordingly, it has to be understood that the invention is not to be limited by the specific illustrative embodiments, but only by the scope of the appended claims.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of the elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. A system adapted to inspect an object including a flexible wire, comprising:
a feed device adapted to feed the object toward an inspection device in a feed direction;
a movable magnet adapted to secure the wire of the object thereto as it approaches the inspection device; and
a movable wire holding fixture adapted to engage with the wire secured by the magnet and maintain the wire in a predetermined position relative to the object to be inspected.

2. The system of claim 1, further comprising a first actuator operatively connected to the magnet and adapted to position the magnet and the wire secured thereto relative to the object to be inspected.

3. The system of claim 2, wherein the first actuator is movable between a first position proximate to the object and a second position distal to the object.

4. The system of claim 3, further comprising a second actuator operatively connected to the wire holding fixture and adapted to position and maintain the wire in a predetermined position relative to the object.

5. The system of claim 4, wherein the second actuator is adapted to bias the wire holding fixture in the feed direction as the object moves in the feed direction.

6. The system of claim 5, further comprising a third actuator operatively connected to the wire holding fixture.

7. The system of claim 6, wherein the third actuator is adapted to bias the wire holding fixture in a direction normal to the feed direction.

8. The system of claim 7, wherein the third actuator biases the wire holding fixture vertically in response to the second actuator stopping motion of the wire holding fixture in the feed direction.

9. The system of claim 8, wherein the vertical motion of the wire holding fixture is operative to remove a bend in the wire resulting from stoppage of the wire holding fixture in the feed direction.

10. The system of claim 1, wherein the wire holding fixture defines a notch adapted to capture the wire secured by the magnet.

11. The system of claim 1, wherein the inspection device includes a plurality of cameras arranged radially about a central axis of the object to be inspected.

12. The system of claim 11, wherein the wire holding fixture is adapted to maintain the wire outside of a field of view of each of the plurality of cameras as the wire holding fixture is translated in the feed direction.

13. A system for visually inspecting an object including a flexible wire, comprising:
an inspection device adapted to receive the object to be inspected in a feed direction;
a magnet adapted to secure the flexible wire of the object as it approaches the inspection device;
a first actuator adapted to bias the magnet and the wire from a first position proximate to the object to be inspected, to a second position distal to the object to be inspected;
a wire holding fixture adapted to capture the wire from the second position; and
a second actuator adapted to translate the wire holding fixture and the wire toward the inspection device in the feed direction as the object to be inspected approaches the inspection device.

14. The system of claim 13, further comprising a third actuator adapted to translate the wire holding fixture in a direction normal to the feed direction in response to the second actuator ceasing to translate the wire holding fixture in the feed direction.

15. The system of claim 14, wherein the first, second and third actuators are linear actuators.

16. The system of claim 13, wherein the inspection device includes a plurality of imaging devices.

17. The system of claim 16, wherein as the second actuator translates the wire holding fixture in the feed direction, the wire remains out of a field of view of at least a portion of the plurality of imaging devices.

18. The system of claim 17, wherein the plurality of imaging devices include at least four imagine devices arranged radially about the object to be inspected.

19. The system of claim 13, wherein the wire holding fixture defines a notch open in the feed direction and adapted to capture the wire secured by the magnet as the wire holding fixture is translated in the feed direction by the second actuator.

20. A method of inspecting an object that includes an exposed flexible wire, comprising:
feeding a portion of the object that does not include the exposed flexible wire through a visual inspection device in a feed direction;
as the exposed wire approaches the visual inspection device, securing the wire to a magnet;
translating the magnet and the wire away from the object;
capturing the wire with a wire holding fixture in a position in which the wire is outside of a field of view of the visual inspection device;
as the object is continually fed through the visual inspection device, translating the wire holding fixture along with the wire in the feed direction;
stopping the wire holding fixture as it approaches an end of a range of travel in the feed direction; and
translating the wire holding fixture in a direction normal to the feed direction as the object continues toward the visual inspection device.
